(19) United States
(12) Patent Application Publication
(10) Pub. No.: US 2008/0224196 A1
(43) Pub. Date: Sep. 18, 2008

(54) SEMICONDUCTOR DEVICE AND MANUFACTURING PROCESS FOR THE SAME

(75) Inventors: Tomohiko HIGASHINO, Kanagawa (JP); Nobuyuki KATSUKI, Kanagawa (JP); Yasuhiro KAWAKATSU, Kanagawa (JP); Michihiro KOBAYASHI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 12/040,315

(22) Filed: Feb. 29, 2008

(30) Foreign Application Priority Data
Mar. 15, 2007 (JP) 2007-066365

(51) Int. Cl. H01L 27/11; H01L 21/70

(52) U.S. Cl. 257/296; 438/210; 257/E27.098; 257/E21.598

(57) ABSTRACT

A semiconductor device includes a first inverter, a second inverter, and an inner wiring connecting the inverters, in which the inner wiring forms a capacitor element, and the capacitor element includes an interlayer insulation film having an aperture on a semiconductor substrate, a lower electrode covering a bottom wall and a side wall of the aperture, the bottom wall being the semiconductor substrate and the side wall being a part of the interlayer insulation film, a capacitor insulation film arranged on the lower electrode and a part of the interlayer insulation film, the capacitor insulation film covering corners of the capacitor insulation film, the corners being situated at opposite side of the semiconductor substrate, and an upper electrode on the capacitor insulation film, the upper electrode covering the aperture.

### BACKGROUND OF THE INVENTION

1. Field of the Invention

This invention relates to a semiconductor device and a manufacturing process for the same. Particularly, this invention relates to the semiconductor device, which has a structure to prevent a soft error caused by radiation from occurring, and the manufacturing process for the same.

2. Description of Related Art

With a development of microfabrication technology, semiconductor devices have been highly integrated at high speed. One of these semiconductor devices that are integrated highly is a static random access memory (SRAM). The SRAM generally includes two complementary metal-oxide semiconductor inverters (CMOS inverters). An input of one CMOS inverter is connected to an output of the other CMOS inverter at one connection node, and an output of one CMOS inverter is connected to an output of the other CMOS inverter at the other connection node. Hereinafter, these connection nodes are called nodes n1 and n2.

As the SRAM cell has been more and more miniaturized, gate capacitance and junction capacitance of a diffused layer in the metal-oxide-semiconductor field-effect transistor (MOSFET) connected to the nodes n1 and n2 are decreased. When the SRAM cell receives radiation from outside, radiation induces electron-hole pairs in a semiconductor substrate. Some of the electron-hole pairs leak into the diffused layer operating as a drain and data memorized in the SRAM cell is inverted. Hence, the SRAM cell cannot memorize data correctly. This phenomenon is called soft error phenomenon. Due to the soft error phenomenon, according to scale-down of the SRAM cell, decreasing of gate capacitance and junction capacitance of the MOSFET which are connected to the nodes n1 and n2 is pronounced compared with electron-hole pairs caused by radiation. Recently, for the highly integrated SRAM, the soft error phenomenon is one of the most major problems.

There are some approaches to prevent false operation caused by the soft error phenomenon from occurring. One of the approaches is to provide capacitors to the nodes n1 and n2 of SRAM cell. With providing the capacitors to the nodes n1 and n2, sufficient electrical charges can be obtained in the nodes n1 and n2 and the soft error phenomenon can be prevented from occurring. This approach of providing the capacitors to the nodes n1 and n2 as above is disclosed in Japanese Unexamined Patent Publication Nos. 2005-183420, 2002-289703 and 2002-076143.

FIG. 14 is a cross sectional view of the related semiconductor device described in Japanese Unexamined Patent Publication No. 2005-183420. FIG. 14 shows a configuration of the capacitor provided to the nodes n1 and n2 (corresponding to FIGS. 7 and 8 in Japanese Unexamined Patent Publication No. 2005-183420). A first interlayer insulation film 202 and a second interlayer insulation film 203 are formed on a semiconductor substrate 201. An aperture 208 is formed in the second interlayer insulation film 203. A first lower electrode 204 is formed on a side wall and a bottom wall of the aperture 208. A second lower electrode 205 is implanted in the aperture 208. The first lower electrode 204 and the second lower electrode 205 correspond to a node line for the node n1 or n2 as described above. A capacitor insulation film 206 is formed on a whole surface of the second interlayer insulation film 203, the first lower electrode 204 and the second lower electrode 205. An upper electrode 207 is formed on a part of the capacitor insulation film 206. A capacitor is composed of a lower electrode including the first lower electrode 204 and the second lower electrode 205, the capacitor insulation film 206 and the upper electrode 207. This capacitor corresponds to the capacitor provided for the nodes n1 and n2.

Hereinafter, a manufacturing process for the semiconductor device will be described. As described in FIG. 15, the first interlayer insulation film 202 and the second interlayer insulation film 203 are formed on the semiconductor substrate 201. The aperture 208 is formed selectively in the second interlayer insulation film 203. Known photolithography and dry etching can be used for forming the aperture 208 and detailed explanation is omitted.

As shown in FIG. 16, the first lower electrode 204 is formed along a principal plane 203a of the second interlayer insulation film 203 and the side wall and the bottom wall of the aperture 208. The second lower electrode 205 is formed so as to fill the aperture 208.

Using known etching, chemical or mechanical polishing, for example, the second lower electrode 205 and the first lower electrode 204 are removed until the principal plane 203a of the second interlayer insulation film 203 is exposed. As shown in FIG. 17, the aperture 208 is filled with the first lower electrode 204 and the second lower electrode 205.

As shown in FIG. 18, a conductive layer which will be the capacitor insulation film 206 and the upper electrode 207 is formed by deposition. The upper electrode 207 is formed by patterning the conductive layer.

However, in this related semiconductor device as described above, sufficient insulation performance of the capacitor insulation film 206 cannot be obtained. Hereinafter, this reason will be explained. FIG. 19 shows the detailed second lower electrode 205. The first lower electrode 204 is formed along an inner wall of the aperture 208. The aperture 208 for wiring is filled with the second lower electrode 205. A capacitor is composed of the capacitor insulation film 206 and the upper electrode 207 in addition to the first lower electrode 204 and the second lower electrode 205. As shown in FIG. 19, the second lower electrode 205 is formed by chemical vapor deposition with tungsten. With microscopic observation on the aperture 208, tungsten column crystals, which grow from the side wall and the bottom wall of the aperture 208, are implanted in the aperture 208. Hence, when line width is narrow, that is, width of the aperture 208 is narrow, tungsten column crystals which grow from the both side walls reach with each other at the center of aperture 208. At the center of aperture 208, growth of tungsten column crystals stops. Hence, a minute hollow whose width is from a few Angstrom to 10 Angstrom is formed around the center of aperture 208. The hollow is called seam. As a result, gaseous material, which grows the capacitor insulation film 206 formed on the connection line (the lower electrodes 204, 205), flows uneven around the hollow. Composition of the capacitor insulation film 206 is uneven around the hollow and insulation performance of capacitance insulation film 206 around the center of aperture 208 gets worse. Hence, sufficient insulation performance of the capacitance insulation film 206 cannot be obtained.

Japanese Unexamined Patent Publication Nos. 2002-289703 and 2002-076143 disclose other capacitor configurations. However, insulation performance of capacitor insulation film also deteriorates because of other reasons. With FIG. 20 and the later figures, manufacturing process in Japanese Unexamined Patent Publication Nos. 2002-289703, 2002-076143 will be described. A planar layout is different between Japanese Unexamined Patent Publication Nos. 2002-289703 and 2002-076143, and configuration only around node lines composing the capacitor will be described and explanation about the other configuration is omitted. As shown in FIG. 20, the aperture 208 is formed in the second interlayer insulation film 203. As shown in FIG. 21, a lower electrode 212 is deposited on whole plane including the side wall and the bottom wall of the aperture 208. A photoresist 210 is formed only in the aperture 208. For this method for forming the lower electrode 212, known technique can be used. For example, after the photoresist 210 is wholly deposited, the photoresist 210 is removed with dry etching until a principal plane 212a of the lower electrode 212 is exposed. An exposed portion of the lower electrode 212 is removed using the photoresist 210 as a mask. The photoresist is removed. Hence, as shown in FIG. 22, the lower electrode 212 is formed only on the side wall and the bottom wall of the aperture 208. The lower electrode 212 is a node electrode of the capacitor. As shown in FIG. 23, the capacitor insulation film 206 is wholly deposited and the upper electrode 207 is deposited on the capacitor insulation film 206.

The upper electrode 207 is etched until a principal plane 206a of the capacitor insulation film 206 is exposed. As shown in FIG. 24, the upper electrode 207 is formed only in the aperture 208. A line for connecting to a ground voltage is formed as 211 shown in FIG. 25, because the upper electrode 207 is formed only in the aperture 208. As described above, an embodiment in Japanese Unexamined Patent Publication No. 2002-289703 is formed. In addition, the line 211 is formed in a suitable planar shape for connecting to a ground voltage.

When the capacitor insulation film 206 is exposed as shown in FIG. 24 in the final step for etching process of the upper electrode 207 in FIG. 23, the capacitor insulation film 206 is exposed to atmosphere of etching process. Hence, the exposed capacitor insulation film 206 is damaged. Insulation properties between the upper electrode 207 and the lower electrode 212 at an upper portion of aperture 208 deteriorate. More properly, the exposed capacitor insulation film 206 is entirely damaged by being exposed to atmosphere of etching process, and insulation properties most deteriorate at the upper portion 206b of the capacitor insulation film 206. The upper portion 206b is the closest portion to the electrodes of capacitor. The upper electrode 207 is generally etched with chlorine atoms generated by ionizing chlorine gas in plasma state for example. In the plasma state, for example, electromagnetic ray, ionized chlorine atoms and the like get into the capacitor insulation film 206 and break binding between atoms which form the capacitor insulation film. As a result, insulation properties get worse.

The same configuration corresponding to the configuration in FIGS. 10 and 12 of Japanese Unexamined Patent Publication No 2002-289703 is disclosed in FIG. 18 of Japanese Unexamined Patent Publication No. 2002-076143, but manufacturing process is by no means disclosed. The configuration in Japanese Unexamined Patent Publication No. 2002-076143 is same as the configuration in Japanese Unexamined Patent Publication No. 2002-289703 and it is considered that insulation properties of the capacitor insulation film also deteriorate in Japanese Unexamined Patent Publication No. 2002-076143. As described above, the related art described in Japanese Unexamined Patent Publication Nos. 2005-183420, 2002-289703 and 2002-076143 have a problem that enough insulation properties cannot be obtained.

The capacitor configuration described above is also disclosed in Japanese Unexamined Patent Publication Nos. 2000-164831 and 2001-168301. However, these descriptions for the related art disclose configuration of memory capacitance in DRAM (Dynamic Random Access Memory). Hence, configurations in Japanese Unexamined Patent Publication Nos. 2000-164831 and 2001-168301 are applied to the other field which is different from this invention. This invention is applied to the SRAM in which the connecting line between the nodes also functions as one of the capacitor electrode.

As described above, insulation properties of a part of capacitor insulation film, which is formed on the connection line between nodes in the SRAM cell, deteriorate. For the related arts, leak current flowing between the nodes and ground GND becomes higher.

### SUMMARY

According to an aspect of this invention, a semiconductor device includes a first inverter, a second inverter, and an inner wiring connecting the inverters, in which the inner wiring forms a capacitor element, and the capacitor element includes an interlayer insulation film having an aperture on a semiconductor substrate, a lower electrode covering a bottom wall and a side wall of the aperture, the bottom wall being the semiconductor substrate and the side wall being a part of the interlayer insulation film, a capacitor insulation film arranged on the lower electrode and a part of the interlayer insulation film, the capacitor insulation film covering corners of the capacitor insulation film, the corners being situated at opposite side of the semiconductor substrate, and an upper electrode on the capacitor insulation film, the upper electrode covering the aperture.

According to an another aspect of this invention, a manufacturing process for a semiconductor device includes, depositing a first insulation film on one principal plane of a semiconductor substrate, the semiconductor substrate including MOSFETs, selectively removing at least a part of the first insulation film for forming an aperture; forming a lower electrode on a bottom wall and at least a part of a side wall of the aperture, depositing a second insulation film, the second insulation film at least covering the lower electrode, and forming an upper electrode, the upper electrode at least covering the lower electrode with the second insulation film interposed therebetween.

According to further another aspect of this invention, a semiconductor device includes a substrate, an insulation film having an opening over the substrate, the opening having a bottom and walls, and a capacitor being formed over the opening, wherein the capacitor includes, a lower electrode covering the walls, a capacitor insulation film covering the lower electrode, an upper electrode covering the capacitor insulation film, and filling at least a part of a remaining portion of the opening, and wherein the upper electrode covers the opening.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram of SRAM according to an embodiment in this invention;

FIG. 2 is a simple planar layout of SRAM as an example in this invention;

FIG. 3 is a planar view showing a layout of wiring layers 31 (31A-31F) overlapped with impurity diffused regions 21, 22 and gate electrodes 23A-23C in a SPAM cell in FIG. 2 in this invention;

FIG. 4 is a planar view showing a layout of via holes connecting wiring layers 31 (31A-31F) in FIG. 3 and the impurity diffused regions 21, 22 or the gate electrodes 23A-23C in FIG. 2 in this invention;

FIG. 5 is a sectional view of peripheral parts of around the wiring layers 31A and 31D in an A-A′ cross sectional view in FIG. 3 in this invention;

FIG. 6 is a sectional view showing a first manufacturing process for the SRAM cell in this invention;

FIG. 7 is a sectional view showing a second manufacturing process for the SRAM cell in this invention;

FIG. 8 is a sectional view showing a third manufacturing process for the SRAM cell in this invention;

FIG. 9 is a sectional view showing a fourth manufacturing process for the SRAM cell in this invention;

FIG. 10 is a sectional view showing a fifth manufacturing process for the SRAM cell in this invention;

FIG. 11 is a sectional view showing a sixth manufacturing process for the SRAM cell in this invention;

FIG. 12 is a sectional view showing a seventh manufacturing process for the SRAM cell in this invention;

FIG. 13 is a sectional view showing an eighth manufacturing process for the SRAM cell in this invention;

FIG. 14 is an enlarged diagram showing a configuration of a capacitor provided for nodes n1 and n2 in the related semiconductor device in Japanese Unexamined Patent Publication No. 2005-183420;

FIG. 15 is a sectional view showing a first manufacturing process in Japanese Unexamined Patent Publication No. 2005-183420;

FIG. 16 is a sectional view showing a second manufacturing process in Japanese Unexamined Patent Publication No. 2005-183420;

FIG. 17 is a sectional view showing a third manufacturing process in Japanese Unexamined Patent Publication No. 2005-183420;

FIG. 18 is a sectional view showing a fourth manufacturing process in Japanese Unexamined Patent Publication No. 2005-183420;

FIG. 19 is an enlarged diagram of a semiconductor device in Japanese Unexamined Patent Publication No. 2005-183420;

FIG. 20 is a sectional view showing a first manufacturing process in Japanese Unexamined Patent Publication No. 2002-289703;

FIG. 21 is a sectional view showing a second manufacturing process in Japanese Unexamined Patent Publication No. 2002-289703;

FIG. 22 is a sectional view showing a third manufacturing process in Japanese Unexamined Patent Publication No. 2002-289703;

FIG. 23 is a sectional view showing a fourth manufacturing process in Japanese Unexamined Patent Publication No. 2002-289703;

FIG. 24 is a sectional view showing a fifth manufacturing process in Japanese Unexamined Patent Publication No. 2002-289703; and

FIG. 25 is a sectional view showing a sixth manufacturing process in Japanese Unexamined Patent Publication No. 2002-289703.

### DETAILED DESCRIPTION OF PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

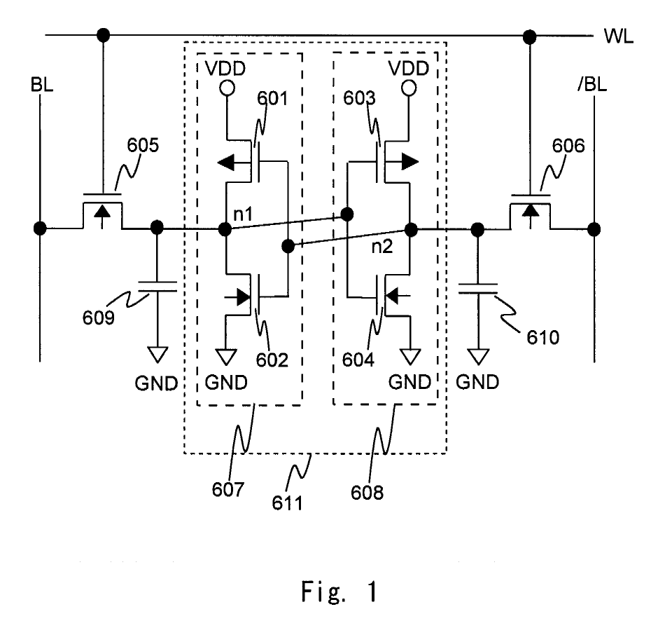

Hereinafter, with reference to the attached drawings, an embodiment in this invention will be described. FIG. 1 is a circuit diagram of a semiconductor device according to the embodiment in this invention. Hereinafter, an SRAM cell including two CMOS inverters to which this invention is applied, will be described. As shown in FIG. 1, the SRAM cell according to the embodiment includes two CMOS inverters 607 and 608. The CMOS inverter 607 comprises a PMOS (positive channel MOS) transistor 601 and an NMOS (negative channel MOS) transistor 602. The CMOS inverter 608 comprises a PMOS transistor 603 and an NMOS transistor 604. In these two inverters 607 and 608, input of one CMOS inverter is connected to output of the other inverter. Hereinafter, these connection nodes are called nodes n1 and n2.

The node n1 functions as both input of the CMOS inverter 608 and output of the CMOS inverter 607. The node n2 functions as both input of the CMOS inverter 607 and output of the CMOS inverter 608. Charges based on data are stored in a gate capacitance of MOS transistors 603 and 604 connected to the node n1, and a junction capacitance of a diffused layer between drain regions of PMOS transistor 601 and NMOS transistor 602. Similarly, charges based on data are stored in a gate capacitance of MOS transistors 601 and 602 connected to the node n2 and a junction capacitance of a diffused layer between drain regions of PMOS transistor 603 and NMOS transistor 604. Hence, in the SRAM cell, data can be stored in the nodes n1 and n2.

Transfer transistors 605 and 606 are provided between a flip-flop circuit 611 comprising two CMOS inverters 607 and 608 and bit line pair (BL and /BL). The transfer transistors 605 and 606 switch connection between the flip-flop circuit 611 and the bit line pair.

In the NMOS transistor 602, source is connected to ground voltage GND, drain to the node n1, and gate to the node n2. In the NMOS transistor 604, source is connected to ground voltage GND, drain to the node n2, and gate to the node n1. In the PMOS transistor 601, source is connected to source voltage VDD, drain to the node n1, and gate to the node n2. In the PMOS transistor 603, source is connected to source voltage VDD, drain to the node n2, and gate to the node n1. In the transfer transistor 605, one terminal is connected to the bit line BL, other terminal to the node n1, and gate to a word line WL. In the transfer transistor 606, one terminal is connected to the complementary bit line /BL, other terminal to the node n2, and gate to the word line WL.

In the SRAM cell configured as described above, at writing data, the bit line pair (BL and /BL) is charged based on data to be written. Voltage is applied to the word line WL so that the transfer transistors 605 and 606 are turned ON. As a result, voltage of the nodes n1 and n2 is same as voltage of corresponding bit lines (BL and /BL). Hence, data is stored in the nodes n1 and n2. At reading data, voltage is applied to the word line WL and voltage of the nodes n1 and n2 is connected to the corresponding bit lines (BL and /BL). Voltage of the bit lines is detected by sense amplifier (not shown). Hence, data stored in the flip-flop circuit 611 can be read out.

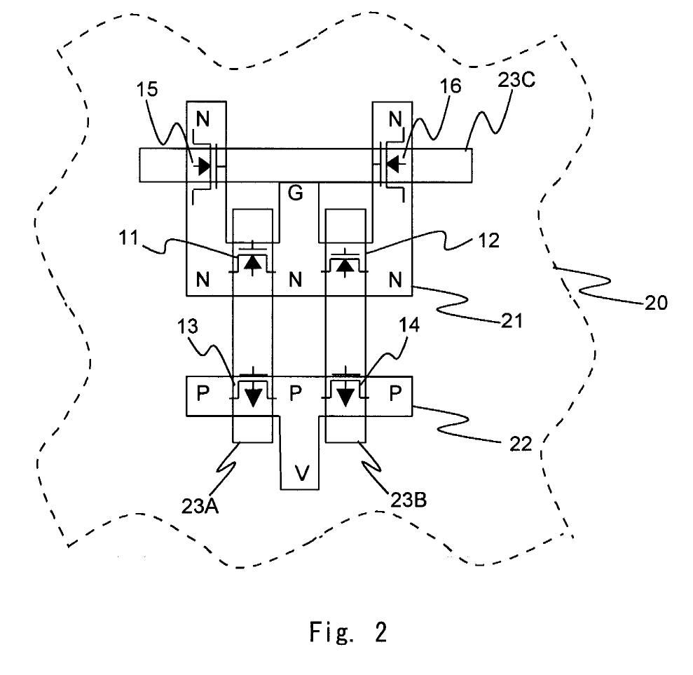

For the SRAM cell configured above, specific configuration on a semiconductor substrate will be described. FIG. 2 is a simple planar layout of SRAM as an example. FIG. 2 is planar view showing a layout of impurity diffused regions 21 and 22, and gate electrodes 23 (23A, 23B and 23C). FIG. 2 is shown only for illustrative purposes and therefore size of components in FIG. 2 does not reflect the actual size.

On the semiconductor substrate 20, an N type impurity diffused region 21 and a P type impurity diffused region 22 are selectively formed. The N type impurity diffused region 21 and the P type impurity diffused region 22 are formed by selectively implanting N type impurities and P type impurities into the semiconductor substrate 20 with ion-implantation or the like and spreading the implanted impurities. The N type impurity diffused region 21 functions as source or drain region of NMOS transistors 11, 12, 15 and 16. The P type impurity diffused region 22 functions as source or drain region of PMOS transistors 13 and 14. Each of the transistors 11, 12, 13, 14, 15, 16 in FIG. 2 corresponds to the transistors 602, 604, 601, 603, 605, 606 in FIG. 1, respectively.

In FIG. 2, gate electrodes 23 (23A-23C) having predetermined pattern are formed on the N type impurity diffused region 21 and the P type impurity diffused region 22 with gate insulator (not shown) interposed therebetween. The gate electrode 23A functions as common gate between the NMOS transistor 11 formed in the N type impurity diffused region 21 and the PMOS transistor 13 formed in the P type impurity diffused region 22. The gate electrode 23B functions as common gate between the NMOS transistor 12 formed in the N type impurity diffused region 21 and the PMOS transistor 14 formed in the P type impurity diffused region 22. The gate electrode 23C functions as common gate between the transfer transistors 15 and 16 formed in the N type impurity diffused region 21. The gate electrode 23C is formed so as to extend in a horizontal direction in the sheet and functions as the word line WL noted previously.

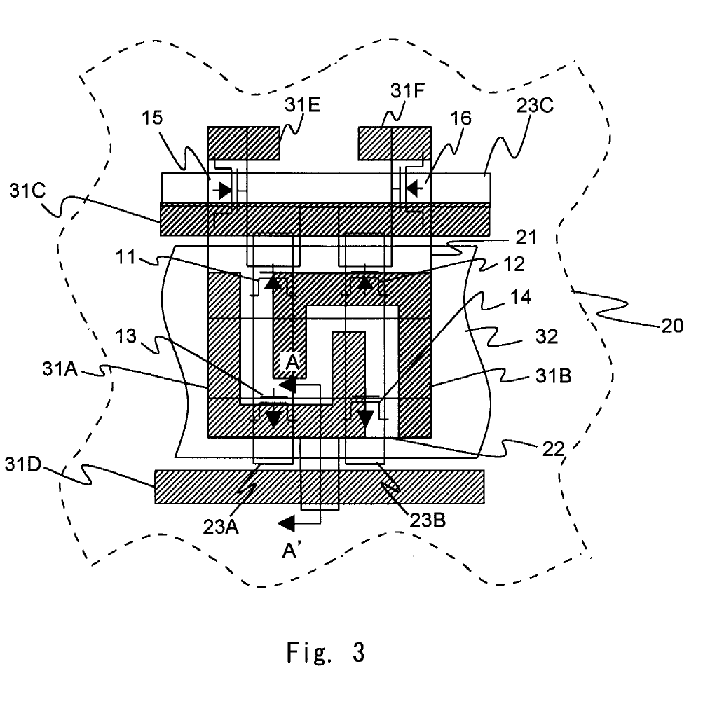

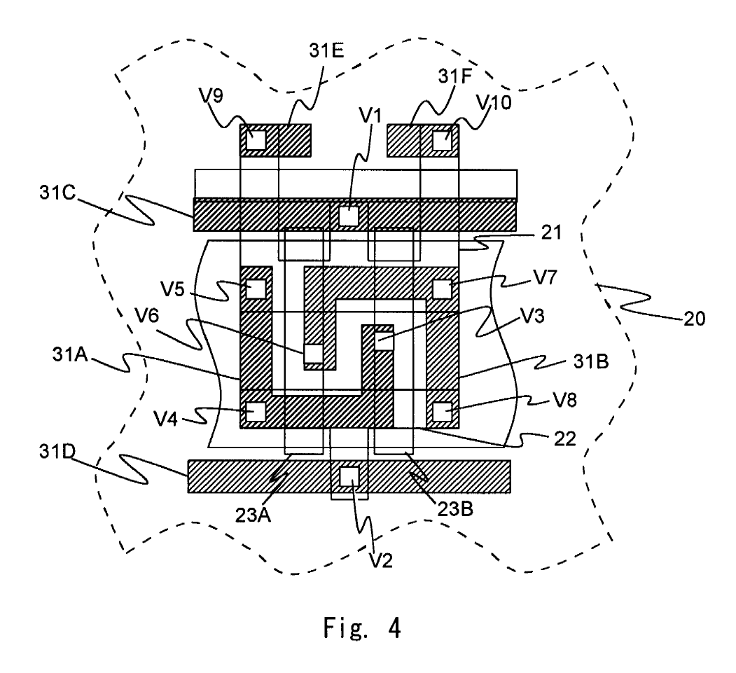

FIG. 3 is a planar view showing a layout of wiring layers 31 (31A-31F) overlapped with impurity diffused regions 21, 22 and gate electrodes 23A-23C in a SRAM cell. FIG. 4 is a planar view showing a layout of via holes connecting wiring layers 31 (31A-31F) in FIG. 3 and the impurity diffused regions 21, 22 or the gate electrodes 23A-23C in FIG. 2. FIGS. 3 and 4 are shown only for illustrative purposes and therefore size of components in FIGS. 3 and 4 does not reflect the actual size. Wiring layers 31 having a predetermined pattern are formed on the impurity diffused regions 21, 22 and the gate electrodes 23. The wiring layers 31 (31A-31F) are connected to lower impurity diffused regions 21 and 22 through via holes (V1 and V2 in FIG. 4). The via holes are formed at predetermined position.

The wiring layer 31A in FIG. 3 is connected to drain region of the NMOS transistor 11, drain region of the PMOS transistor 13 and the gate electrode 23B through via holes V5, V4 and V3 in FIG. 4. That is, the wiring layer 31A is formed to function as the node n1 in FIG. 1. The wiring layer 31B is connected to drain region of the NMOS transistor 12, drain region of the PMOS transistor 14 and the gate electrode 23A through the via holes V7, V8 and V6 in FIG. 4. That is, the wiring layer 31B is formed to function as the node n2 in FIG. 1.

The wiring layer 31C is formed so as to extend from right side to left side in the sheet and functions as a ground voltage supply line GND which supplies ground voltage to the SRAM cells. The ground voltage supply line GND is shared by the SRAM cells. The wiring layer 31D is connected to source regions of the PMOS transistors 13 and 14 through the via holeV2 in FIG. 4. The wiring layer 31D is also formed so as to extend from right side to left side in the sheet and functions as a source voltage line VCC which supplies source voltage to the SRAM cells. The source voltage line VCC is shared by the SRAM cells. The wiring layer 31E is connected to one diffused layer region of the transfer transistor 15 (NMOS transistor) through a via hole V9 in FIG. 4. This diffused layer region is connected to the bit line. The wiring layer 31E is connected to the bit line BL which is formed in other upper wiring layer (not shown) than the wiring layer 31.

The wiring layer 31F is connected to one diffused layer region of the transfer transistor 16 (NMOS transistor) through the via hole V10 in FIG. 4. This diffused layer region is connected to the bit line. The wiring layer 31F is connected to the complementary bit line /BL which is formed in other upper wiring layer (not shown) than the wiring layers 31. The wiring layer 32 is formed so as to cover at least the wiring layers 31A and 31B with insulation film (not shown) interposed therebetween.

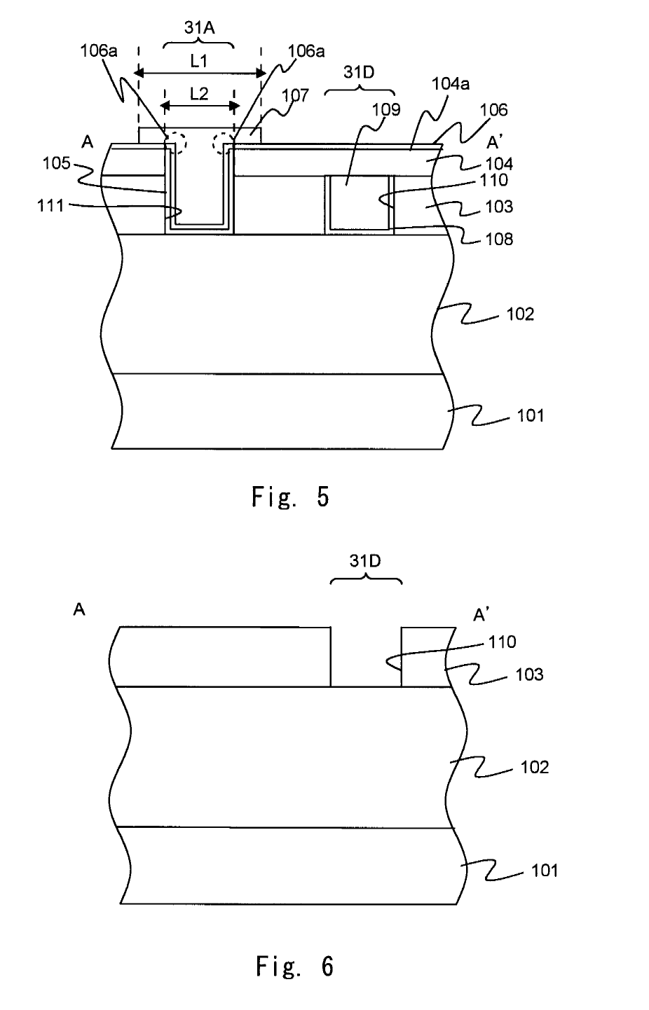

FIG. 5 shows a cross sectional view of peripheral parts of the wiring layers 31A and 31D taken along the line A-A′ of FIG. 3. The semiconductor device includes a semiconductor substrate 101, a first interlayer insulation film 102, a second interlayer insulation film 103, a third interlayer insulation film 104, a lower electrode 105, a capacitor insulation film 106, an upper electrode 107 and conductive layers 108, 109. The impurity diffused regions 21 and 22 formed on the semiconductor substrate 101 in FIG. 2 are omitted for the purpose of simplicity.

The first interlayer insulation film 102 is formed on the semiconductor substrate 101. The second interlayer insulation film 103 is formed on the first interlayer insulation film 102. An aperture 110 is formed in the second interlayer insulation film 103. The conductive layer 108 is formed on an inner wall of the aperture 110 and the conductive layer 109 is implanted in the aperture 110. The third interlayer insulation film 104 is formed on the second interlayer insulation film 103. An aperture 111 is formed so as to penetrate the second interlayer insulation film 103 and the third interlayer insulation film 104. The lower electrode 105 is formed on an inner wall of the aperture 111. The capacitor insulation film 106 is formed on the third interlayer insulation film 104 and the lower electrode 105. The upper electrode 107 is formed so as to cover inner wall and upper corners of the aperture 111. The upper electrode 107 is formed so that width L1 of the upper electrode 107 is wider than width L2 of the aperture 111. The aperture 110 corresponds to the wiring layer 31D and the aperture 111 to the wiring layer 31A.

A surface of the conductive layers 108 and 109 corresponding to the wiring layer 31D is situated at a lower position than a surface of the upper electrode 107. That is to say, a surface of the conductive layers 108 and 109 is formed closer to the substrate than the surface of the upper electrode 107. That is, the surface of the wiring layer 31D supplying source voltage to the first inverter 607 and the second inverter 608 is formed at lower position than the surface of the upper electrode 107. The surface of the wiring layer 31D is closer to the substrate than the surface of the upper electrode 107. The cross sectional view showing peripheral parts of the wiring layers 31A and 31D in FIG. 5 almost corresponds with the cross sectional view showing peripheral parts of the wiring layers 31B and 31C. The wiring layers 31B and 31C are symmetrical to the wiring layers 31A and 31D in the sheet of FIG. 3. That is, a surface of the wiring layer 31C, which supplies ground voltage to the first inverter 607 and the second inverter 608, is formed at lower position than the surface of the upper electrode 107. The surface of the wiring layer 31C is closer to the substrate 101 than the surface of upper electrode 107.

The lower electrode 105 functions as a node line of the node n1 in FIG. 1. The upper electrode 107 only needs to cover the wiring layers 31A and 31B in FIG. 3. FIG. 5 is described as the upper electrode 107 is not on the wiring layer 31D. However, the upper electrode 107 may cover all of or a part of the wiring layer 31D.

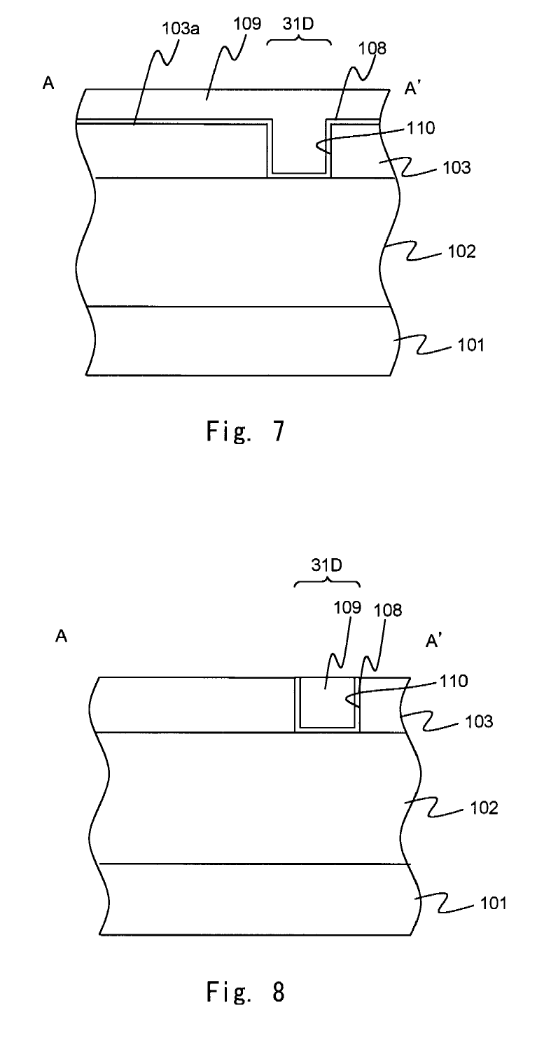

Hereinafter, manufacturing process for the SRAM cell configured as described above will be explained. FIG. 6 is a sectional view showing a first manufacturing process for the SRAM cell. The first interlayer insulation film 102 and the second interlayer insulation film 103 are formed on the semiconductor substrate 101. The aperture 110 corresponding to the wiring layer 31D in the plane view of FIG. 3 is formed in the second interlayer insulation film 103. As shown in FIG. 7, the conductive layer 108 is formed on the side wall and bottom wall of the aperture 110 and the principal plane 103a of the second interlayer insulation film 103. The conductive layer 109 is deposited in the aperture 110 so that the aperture 110 is filled up with the conductive layer 109. With known polishing process or etching process, the conductive layers 108 and 109 are removed until the principal plane 103a of the second interlayer insulation film 103 is exposed. As a result, the conductive layers 108 and 109 are left only in the aperture 110 as shown in FIG. 8.

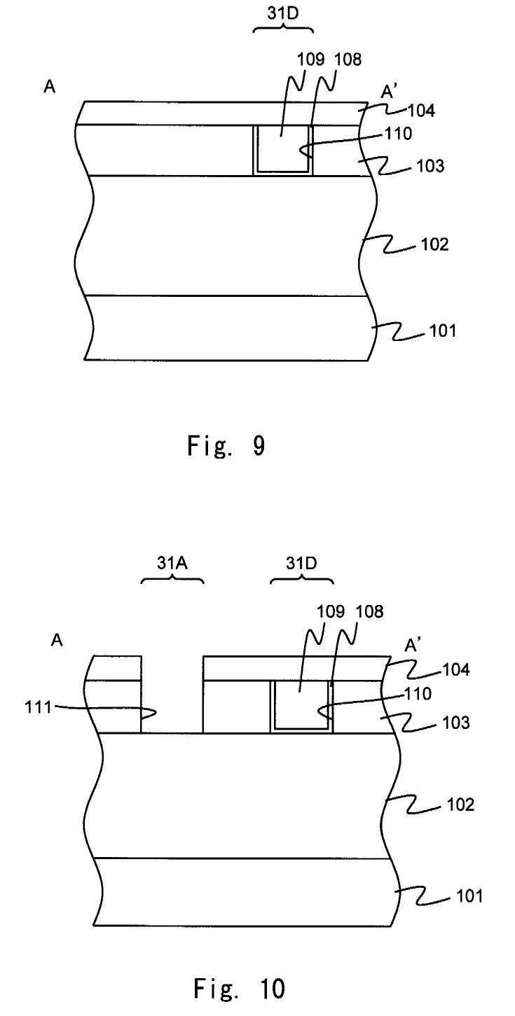

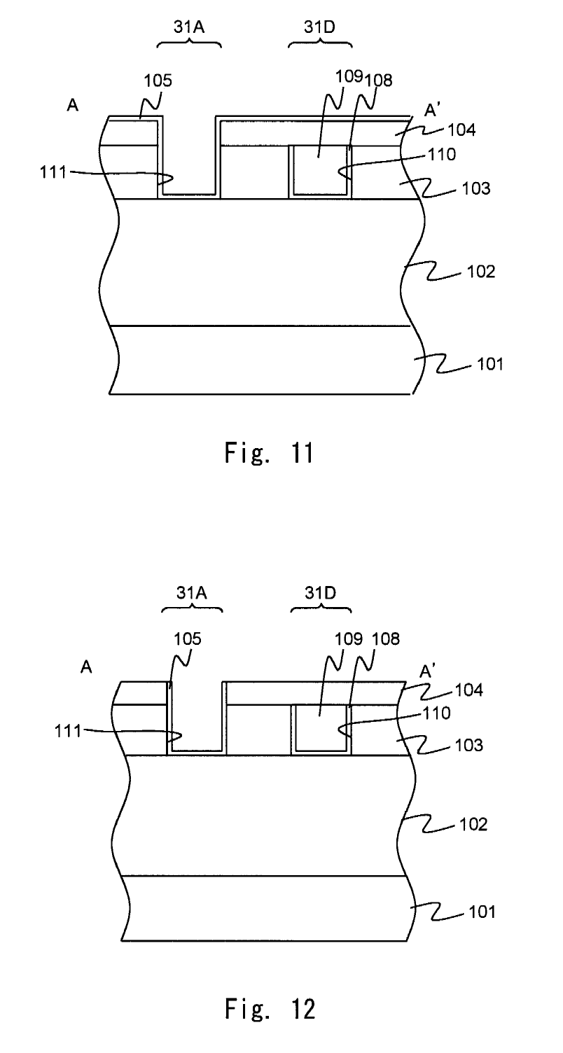

As shown in FIG. 9, the third interlayer insulation film 104 is deposited. As shown in FIG. 10, the aperture 111 (opening) corresponding to the wiring layer 31A in FIG. 3 is formed so as to penetrate the second interlayer insulation film 103 and the third interlayer insulation film 104. The aperture 111 (opening) has a bottom and walls. That is, the aperture 111 has a bottom and a side walls. As shown in FIG. 11, the lower electrode 105 is deposited on the side wall and bottom wall of the aperture 111 and the third interlayer insulation film 104. As shown in FIG. 12, the lower electrode 105 is formed only on the side wall and bottom wall in the aperture. For this process, known method as follows can be used. That is, a resist is left only in the aperture 111 and the exposed electrode 105 is removed. Because the aperture 111 corresponds to the wiring layer 31A in FIG. 3, the lower electrode 105 is a node line configuring the node n1 in FIG. 1.

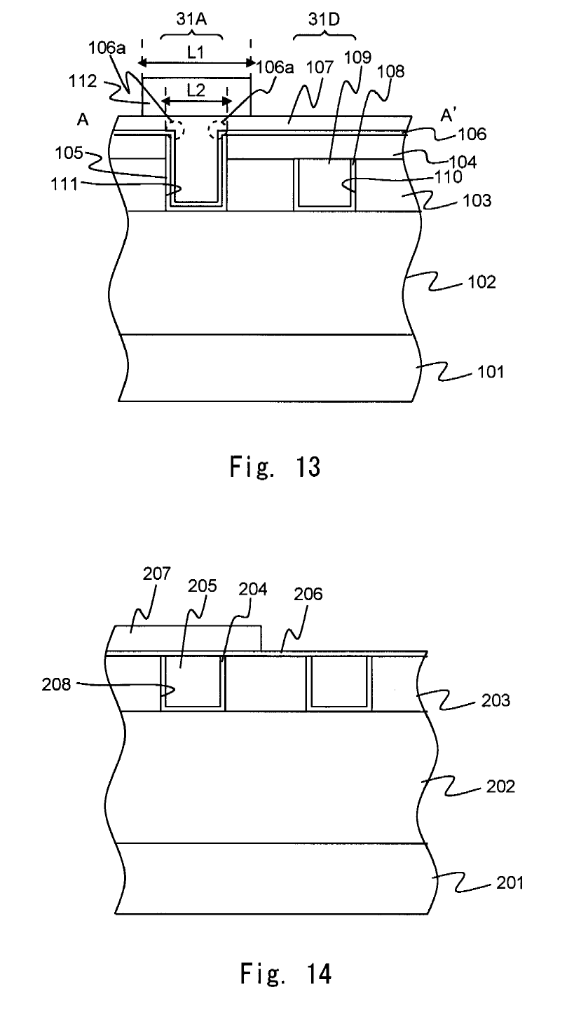

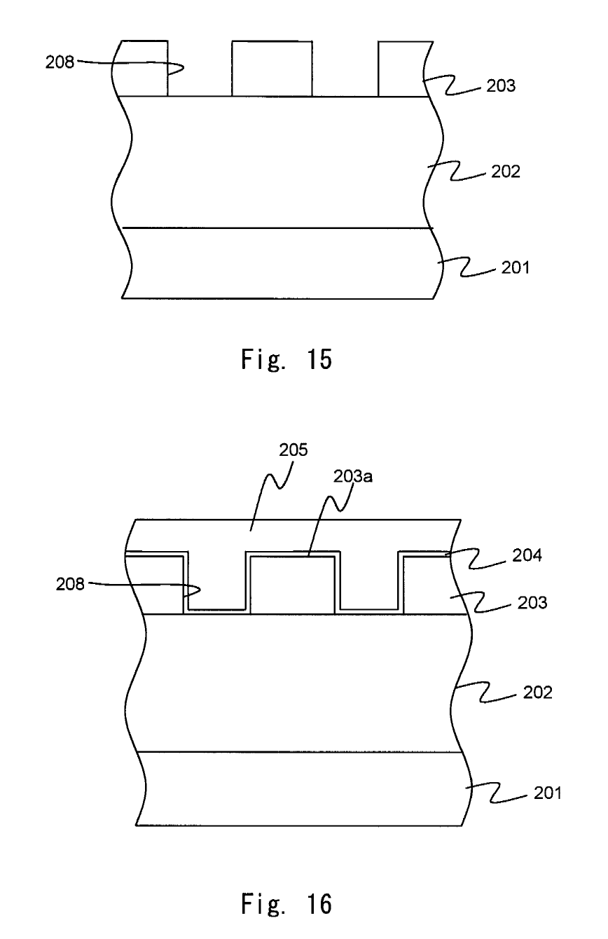

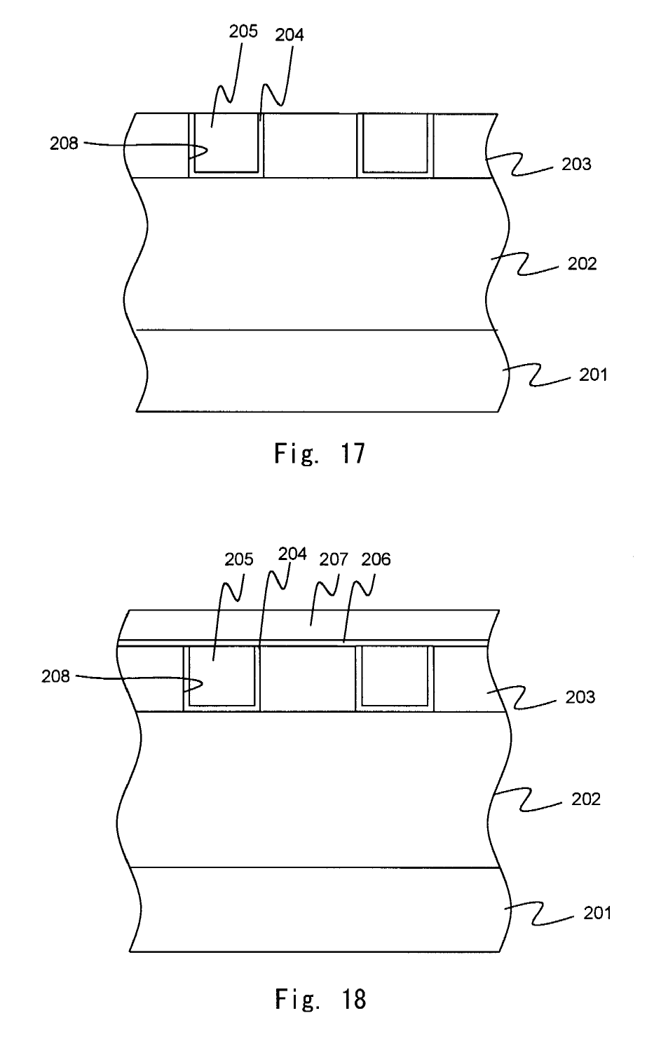

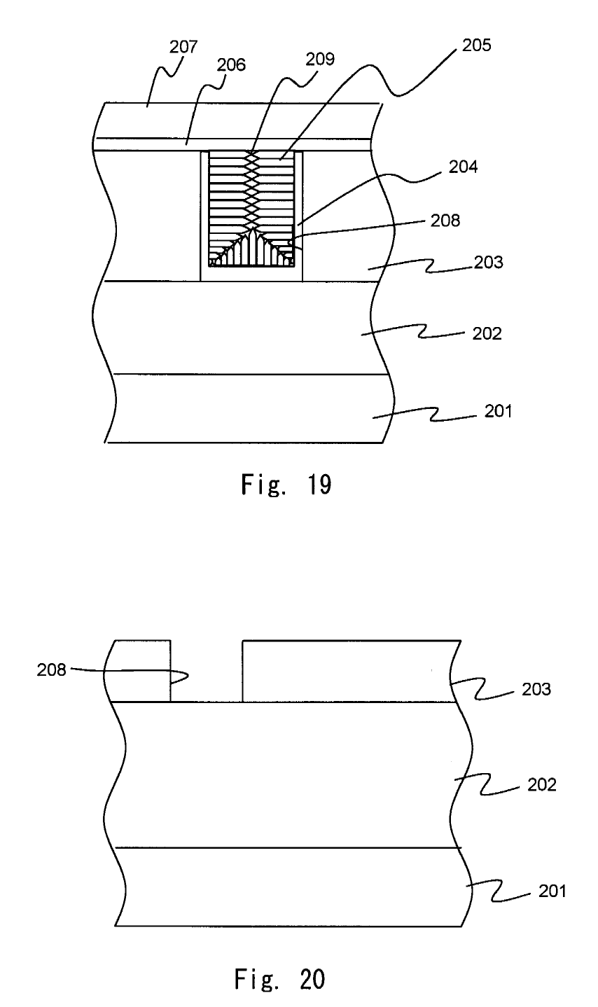

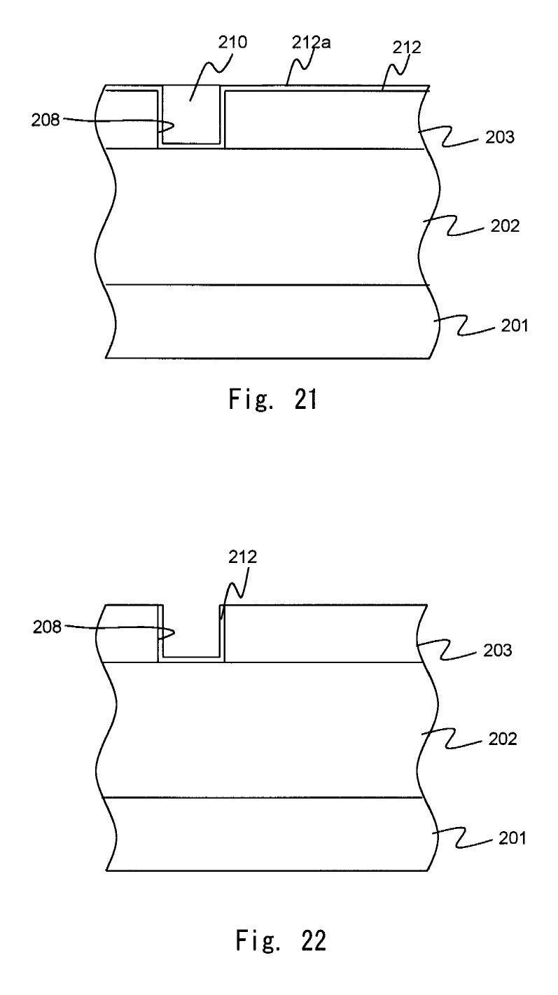

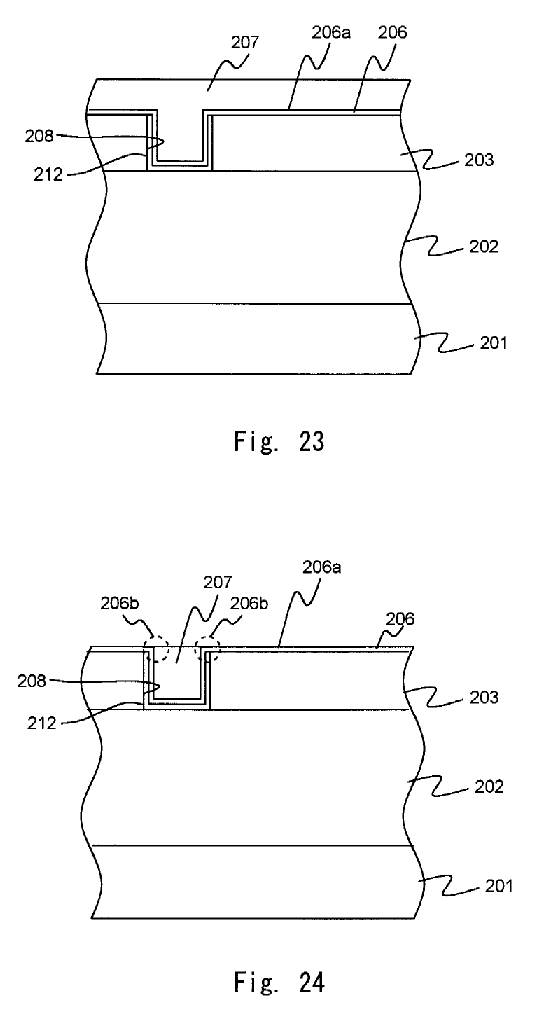

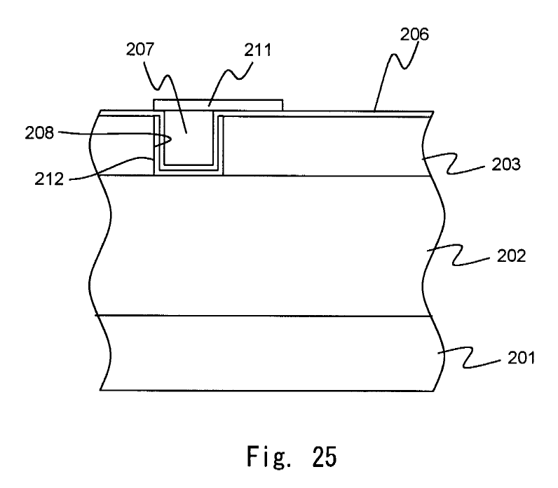

As shown in FIG. 13, the capacitor insulation film 106 is deposited on the whole surface including the surface of the lower electrode 105 covering the side wall and bottom wall in the aperture 111. The upper electrode 107 is deposited on the capacitor insulation film 106. As a result, a capacitor is formed between the lower electrode 105 acting as node line and the upper electrode 107. This capacitor corresponds to the capacitor 609 in FIG. 1.

A photoresist 112 is formed on the upper electrode 107. The upper electrode 107 is etched with the photoresist 112 as a mask. Hence, the cross sectional view in FIG. 5 is obtained. At this time, size of the photoresist 112, that is width L1 of the photoresist 112 in FIG. 13, is set to be wider than width L2 of the aperture 111. The width L1 of the aperture 111 is preferred to be 20% or above larger than the minimum width in the flat plane of the aperture 111. The upper electrode 107 is formed to extend from front side to the back side of the sheet. The upper electrode 107 is connected to the ground voltage GND, which is the other electrode of the capacitor, at different cross section from FIG. 3 and this explanation is omitted.

Hereinafter, advantages of the SRAM cell configured as described above will be explained. As shown in FIG. 5, the upper electrode 107 of the capacitor is formed so as to cover the upper aperture corners 106a of the capacitor insulation film 106 formed on the aperture 111. Hence, as shown in FIG. 13, when the upper electrode 107 is etched, the upper aperture corners 106a of the capacitor insulation film 106 are not exposed to etching atmosphere. Hence, insulation properties of the upper aperture corners 106a of the capacitor insulation film 106 do not deteriorate. As a result, for the capacitor which comprises the lower electrode 105, the capacitor insulation film 106 and the upper electrode 107, insulation performance of the capacitor insulation film 106 can be fully obtained. Hence, performance of the semiconductor device can be improved.

The lower electrode 105 is formed along the inner wall of the aperture 111. Hence, compared with the configuration having aperture 111 filled up with the lower electrode, seam which is generated at implanting the lower electrode can be prevented from occurring. Hence, enough insulation performance of the capacitor insulation film can be obtained.

As described above, planar layouts are shown in FIGS. 2-4. However, the layout of this invention is not limited to them. In this invention, other configurations can be made in many ways as long as the lower electrode 105 is formed on the side wall and bottom wall in the aperture 111 and the upper electrode 107 is formed so as to cover the upper aperture corners 106a of the capacitor insulation film 106. By having such a configuration, advantages in this invention can be obtained. That is, deterioration of the capacitor insulation film 106 can be prevented and enough insulation performance of the capacitor insulation film can be obtained.

It is apparent that the present invention is not limited to the above embodiment, but may be modified and changed without departing from the scope and spirit of the invention.

What is claimed is:

1. A semiconductor device comprising:
a first inverter, a second inverter, and an inner wiring connecting the inverters,
wherein the inner wiring forms a capacitor element, and
the capacitor element includes:
an interlayer insulation film having an aperture on a semiconductor substrate;
a lower electrode covering a bottom wall and a side wall of the aperture, the bottom wall being the semiconductor substrate and the side wall being a part of the interlayer insulation film;
a capacitor insulation film arranged on the lower electrode and a part of the interlayer insulation film, the capacitor insulation film covering corners of the capacitor insulation film, the corners being situated at opposite side of the semiconductor substrate; and
an upper electrode on the capacitor insulation film, the upper electrode covering the aperture.

2. The semiconductor device according to claim 1,
wherein the upper electrode covers the corners of the capacitor insulation film formed on an edge of the aperture.

3. The semiconductor device according to claim 1,
wherein the first and the second inverters are SRAM cells.

4. The semiconductor device according to claim 1,
wherein a width of the upper electrode is larger than a width of the aperture.

5. The semiconductor device according to claim 4,
wherein the width of the upper electrode is 20% or above larger than a minimum width of the aperture.

6. The semiconductor device according to claim 1, further comprising:
a conductive layer supplying a source voltage or a ground voltage to the first and the second inverters,
wherein a surface of the conductive layer is situated closer to the semiconductor substrate than a surface of the upper electrode.

7. A manufacturing process for a semiconductor device comprising:
depositing an interlayer insulation film on one principal plane of a semiconductor substrate, the semiconductor substrate including MOSFETs;
selectively removing at least a part of the interlayer insulation film for forming an aperture;
forming a lower electrode on a bottom wall and at least a part of a side wall of the aperture;
depositing a capacitor insulation film, the capacitor insulation film at least covering the lower electrode; and
forming an upper electrode in the aperture, the upper electrode at least covering the lower electrode with the capacitor insulation film interposed therebetween.

8. The manufacturing process for the semiconductor device according to claim 7,
wherein the upper electrode is formed so as to cover corners of the capacitor insulation film formed on an edge of the aperture.

9. The manufacturing process for the semiconductor device according to claim 7,
wherein forming the upper electrode includes:
depositing the upper electrode on the capacitor insulation film;
depositing a photoresist on the upper electrode, the width being at least larger than a width of the aperture; and
etching the upper electrode with the photoresist as a mask.

10. The manufacturing process for the semiconductor device according to claim 7,
wherein a width of the photoresist is 20% or above larger than a width of the aperture.

11. The manufacturing process for the semiconductor device according to claim 7,
wherein the semiconductor device includes first and second inverters.

12. The manufacturing process for the semiconductor device according to claim 11,
wherein the first and the second inverters are SRAM cells.

13. A semiconductor device comprising:
a substrate;
an insulation film having an opening over the substrate, the opening having a bottom and walls; and
a capacitor being formed over the opening;
wherein the capacitor includes;
a lower electrode covering the walls,
a capacitor insulation film covering the lower electrode,
an upper electrode covering the capacitor insulation film, and filling at least a part of a remaining portion of the opening, and
wherein the upper electrode covers the opening.

14. The semiconductor device according to claim 13,
wherein the capacitor insulation film covers at least a corner of the opening.

15. The semiconductor device according to claim 13,
wherein a width of the upper electrode is larger than a width of the opening.

16. The semiconductor device according to claim 15,
wherein a width of the upper electrode is 20% larger than a width of the opening.

17. The semiconductor device according to claim 13,
wherein the semiconductor device includes first and second inverters.

18. The semiconductor device according to claim 17,
wherein the first and second inverters are SRAM cell.
